(19) United States
(12) Patent Application Publication
(10) Pub. No.: US 2008/0169885 A1
(43) Pub. Date: Jul. 17, 2008

(54) PIEZOELECTRIC THIN-FILM RESONATOR, ACOUSTIC WAVE DEVICE AND METHOD FOR FABRICATING THE ACOUSTIC WAVE DEVICE

(75) Inventors: Masanori Ueda, Kawasaki (JP); Tokihiro Nishihara, Kawasaki (JP); Shinji Taniguchi, Kawasaki (JP); Tsuyoshi Yokoyama, Kawasaki (JP); Go Endo, Yokohama (JP); Yasuyuki Saitou, Yokohama (JP)

Correspondence Address: ARENT FOX LLP, 1050 CONNECTICUT AVENUE, N.W., SUITE 400, WASHINGTON, DC, 20036, US

(73) Assignees: FUJITSU MEDIA DEVICES LIMITED, Yokohama-shi (JP); FUJITSU LIMITED, Kawasaki-shi (JP)

(21) Appl. No.: 11/972,316

(22) Filed: Jan. 10, 2008

(30) Foreign Application Priority Data
Jan. 11, 2007 (JP) 2007-003357

(51) Int. Cl. H01L 41/22; H03H 9/00

(52) U.S. Cl. 333/187; 333/193; 29/25.35

(57) ABSTRACT

A piezoelectric thin-film resonator includes: a lower electrode provided on a substrate; a piezoelectric film provided on the lower electrode; an upper electrode provided on the piezoelectric film so as to face the lower electrode across the piezoelectric film to thus define a resonance portion; and a weight load film provided on the upper electrode, the weight load film being provided in the resonance portion and having an area smaller than that of the resonance portion.

### BACKGROUND OF THE INVENTION

1. Field of the Invention

The present invention generally relates to piezoelectric thin-film resonators, acoustic wave devices and method for fabricating the acoustic wave devices. More particularly, the present invention relates to an acoustic wave device having piezoelectric thin-film resonators having different resonance frequencies, and a method for fabricating such an acoustic wave device.

2. Description of the Related Art

There has been an increasing demand for compact and light resonators and filters using these resonators due to rapid development of mobile communication networks such as cellular phones. In the past, surface acoustic wave (SAW) filters were mainly used. Recently, there has been considerable activity in the development of piezoelectric thin-film resonators that have good high-frequency performance and are miniaturized and monolithically implemented, and filters using such piezoelectric thin-film resonators.

An FBAR (Film Bulk Acoustic Resonator) type resonator is known as one of the piezoelectric thin-film resonators. The FBAR has a film laminate composed of an upper electrode, a piezoelectric film and a lower electrode. A space, which may be a via hole or cavity, is provided below the lower electrode and located within an overlapping region (resonance portion) in which the upper and lower electrodes overlap with each other across the piezoelectric film. The space may be formed below a dielectric film provided under the lower electrode. The via hole may be defined by wet-etching a silicon substrate that may be used as a device substrate from the backside of the silicon substrate. The cavity may be defined by forming the resonator composed of the film laminate on a sacrificed layer on the surface of the substrate and removing the sacrificed layer. In this manner, the piezoelectric thin-film resonators are of via-hole type and cavity type.

A high-frequency signal is applied between the upper electrode and the lower electrode, an acoustic wave is generated within the piezoelectric film sandwiched between the upper and lower electrodes. The acoustic wave thus generated is excited by the reverse piezoelectric effect and distortion arising from the piezoelectric effect. The acoustic wave is totally reflected by the surface of the upper electrode (film) that is in contact with air and the surface of the lower electrode (film) that is in contact with air. Thus, the acoustic wave is a thickness-extensional wave having main displacements in the thickness direction. In the present device structure, the resonance frequency fr is basically determined by the thickness h of the piezoelectric film and is described as fr=nV/2h where n is an odd integer number and V is the acoustic velocity of the piezoelectric film. More specifically, the resonance frequency relates to the thickness, weight, Young's modulus and density of the piezoelectric film and the electrode films, and more particularly, to the thickness and weight of the piezoelectric film and the electrode films. At high frequencies, the thickness and weight of the upper and/or lower electrode (which includes a weight adding film provided on the lower and/or upper electrode) are not negligible. That is, the resonance frequency fr is determined by the thicknesses and weights of the piezoelectric thin film, the lower electrode and the upper electrode. In other words, the resonance frequency can be controlled by the thickness and/or weight of a laminate structure composed of the piezoelectric film, the lower electrode and the upper electrode, so that a piezoelectric thin-film resonator having a desired frequency characteristic can be realized.

The upper and lower electrodes may be a film laminate made of a metal such as aluminum (Al), copper (Cu), molybdenum (Mo), tungsten (W), tantalum (Ta), platinum (Pt), ruthenium (Ru), rhodium (Rh), iridium (Ir), chromium (Cr), or titanium (Ti), or an arbitrary combination of these metals. The piezoelectric film may be aluminum nitride (AlN), zinc oxide (ZnO), lead zirconium titanate (PZT), or lead titanate (PbTiO₃). Preferably, the piezoelectric film is aluminum nitride or zinc oxide having an orientation axis in the (002) direction. The device substrate may be made of silicon (Si), glass or gallium arsenide (GaAs).

A ladder filter is well known as a filter using the piezoelectric thin-film resonators. The ladder filter has a ladder structure in which piezoelectric thin-film resonators are arranged in series arms and parallel arms. It is possible to easily control the insertion loss and out-of-band suppression of the filter by simply changing the number of stages of the ladder structure and the capacitance ratio of the parallel and series thin-film resonators. In addition, the design work is simple. Due to the above advantages, the ladder filter is widely employed. A lattice filter designable in a way similar to that of the ladder filter is also used widely.

The resonance frequencies of the series and parallel resonators are different from each other. It is required that the resonance frequencies of the series resonators are set higher than those of the parallel resonators. Conventionally, there are several methods for making the above frequency difference. It is known that the resonance frequency of the piezoelectric thin-film resonator is inversely proportional to the weight of the laminate structure thereof. That is, the resonance frequency becomes lower as the weight of the laminate structure increases, and becomes higher as the weight of the laminate structure decreases.

For example, Japanese Patent Application Publication No. 2005-286945 discloses a weight load film on the upper electrode of the resonator to change the weight of the laminate structure and to thus control the resonance frequency.

The following documents disclose that a weight load is applied to each of the lower electrode, the piezoelectric film and the upper electrode and a given weight is removed therefrom: Japanese Patent Application Publication Nos. 2002-299979, 2002-299980, 2002-335141, and 2002-344270.

A bandpass filter can be formed by at least two piezoelectric thin-film resonators respectively having different resonance frequencies in the ladder filter or lattice filter. In order to improve the filter performance, it is better that the center frequencies of the piezoelectric thin-film resonators can be designed by a single design parameter. This improves the design flexibility. An arrangement such that multiple bandpass filters having different resonance frequencies are formed on a single chip requires four different piezoelectric thin-film resonators respectively having different resonance frequencies.

For example, Japanese Patent Application Publication No. 2005-286945 discloses a piezoelectric thin-film resonator in which two kind of piezoelectric thin-film resonators having different resonance frequencies may be simultaneously formed on an identical substrate or an identical chip. However, when three kinds of piezoelectric thin-film resonators having mutually different resonance frequencies are formed, the step of forming weight load films must be carried out twice. That is, when n kinds of piezoelectric thin-film resonators having mutually different resonance frequencies may be simultaneously formed on an identical substrate or an identical chip, the step of forming weight load films must be carried out (n−1) times. This increases the number of production steps and increases the cost.

### SUMMARY OF THE INVENTION

The present invention has been made in view of the above circumstances, and provides a piezoelectric thin-film resonator capable of easily controlling the resonance frequency.

The present invention also provides an acoustic wave device having multiple different kinds of piezoelectric thin-film resonators that have different resonance frequencies and can be formed on a single substrate or chip by a simplified production process, and a method for fabricating such an acoustic wave device.

According to an aspect of the present invention, there is provided a piezoelectric thin-film resonator including: a lower electrode provided on a substrate; a piezoelectric film provided on the lower electrode; an upper electrode provided on the piezoelectric film so as to face the lower electrode across the piezoelectric film to thus define a resonance portion; and a weight load film provided on the upper electrode, the weight load film being provided in the resonance portion and having an area smaller than that of the resonance portion.

According to another aspect of the present invention, there is provided an acoustic wave device including a piezoelectric thin-film resonator including: a lower electrode provided on a substrate; a piezoelectric film provided on the lower electrode; an upper electrode provided on the piezoelectric film so as to face the lower electrode across the piezoelectric film to thus define a resonance portion; and a weight load film provided on the upper electrode, the weight load film being provided in the resonance portion and having an area smaller than that of the resonance portion.

According to yet another aspect of the present invention, there is provided an acoustic wave device including piezoelectric thin-film resonators each including: a lower electrode provided on a substrate; a piezoelectric film provided on the lower electrode; an upper electrode provided on the piezoelectric film so as to face the lower electrode across the piezoelectric film to thus define a resonance portion; and a weight load film provided on the upper electrode, the weight load film being provided in the resonance portion and having an area smaller than that of the resonance portion, the piezoelectric thin-film resonators including resonators having the weight load films having an identical area.

According to a further aspect of the present invention, there is provided a method including: forming multiple resonance portions in each of which a lower electrode and an upper electrode face each other across a piezoelectric film; and simultaneously forming weight load films having different areas in the multiple resonance portions.

### BRIEF DESCRIPTION OF THE DRAWINGS

FIG. 1 is a cross-sectional view of a piezoelectric thin-film resonator in accordance with a first comparative example;

FIG. 2 is a graph of a resonance frequency as a function of normalized weight load;

FIG. 3 is a cross-sectional view of a piezoelectric thin-film resonator in accordance with a second comparative example;

FIG. 4A is a cross-sectional view of a resonance portion of a piezoelectric thin-film resonator in accordance with a first embodiment;

FIG. 4B is a cross-sectional view of a resonance portion of a piezoelectric thin-film resonator in accordance with a first variation of the first embodiment;

FIG. 5A is a graph of an impedance vs. frequency characteristic of the second comparative example;

FIG. 5B is a graph of an impedance vs. frequency characteristic of the first embodiment;

FIG. 5C is a graph of an impedance vs. frequency characteristic of the first variation of the first embodiment;

FIGS. 6A through 6D are cross-sectional views of steps of fabricating the piezoelectric thin-film resonators of the second comparative example and the first embodiment on an identical substrate;

FIGS. 7A through 7C are cross-sectional views of steps following the steps of FIGS. 6A through 6D;

FIGS. 8A and 8B are cross-sectional views of steps following the steps of FIGS. 7A through 7C;

FIG. 9 is a plan view of a resonance portion of a piezoelectric thin-film resonator in accordance with a third comparative example;

FIG. 10A is a plan view of a resonance portion of a piezoelectric thin-film resonator in accordance with a second embodiment;

FIG. 10B is a plan view of a resonance portion of a piezoelectric thin-film resonator in accordance with a first variation of the second embodiment;

FIG. 11A is a graph of an impedance vs. frequency characteristic of a third comparative example;

FIG. 11B is a graph of an impedance vs. frequency characteristic of the second embodiment;

FIG. 11C is a graph of an impedance vs. frequency characteristic of a first variation of the second embodiment;

FIG. 12A is a plan view of a resonance portion of a piezoelectric thin-film resonator in accordance with a third embodiment;

FIG. 12B is a plan view of a resonance portion of a piezoelectric thin-film resonator in accordance with a first variation of the third embodiment;

FIG. 12C is a plan view of a resonance portion of a piezoelectric thin-film resonator in accordance with a second variation of the third embodiment;

FIG. 13A is a graph of an impedance vs. frequency characteristic of a third embodiment;

FIG. 13B is a graph of an impedance vs. frequency characteristic of a first embodiment of the third embodiment;

FIG. 13C is a graph of an impedance vs. frequency characteristic of a second variation of the third embodiment;

FIG. 14A is a plan view of a resonance portion of a piezoelectric thin-film resonator in accordance with a fourth embodiment;

FIG. 14B is a plan view of a resonance portion of a piezoelectric thin-film resonator in accordance with a first variation of the fourth embodiment;

FIG. 14C is a plan view of a resonance portion of a piezoelectric thin-film resonator in accordance with a second variation of the fourth embodiment;

FIG. 15A is a graph of an impedance vs. frequency characteristic of the fourth embodiment;

FIG. 15B is a graph of an impedance vs. frequency characteristic of a first embodiment of the fourth embodiment;

FIG. 15C is a graph of an impedance vs. frequency characteristic of a second variation of the fourth embodiment;

FIG. 16A is a plan view of a resonance portion of a piezoelectric thin-film resonator in accordance with a fifth embodiment;

FIG. 16B is a plan view of a resonance portion of a piezoelectric thin-film resonator in accordance with a first variation of the fifth embodiment;

FIG. 17 is a circuit diagram of a ladder type filter; and

FIG. 18 is a circuit diagram of a lattice type filter.

### DESCRIPTION OF THE PREFERRED EMBODIMENTS

A description will now be given of embodiments of the present invention with reference to the accompanying drawings.

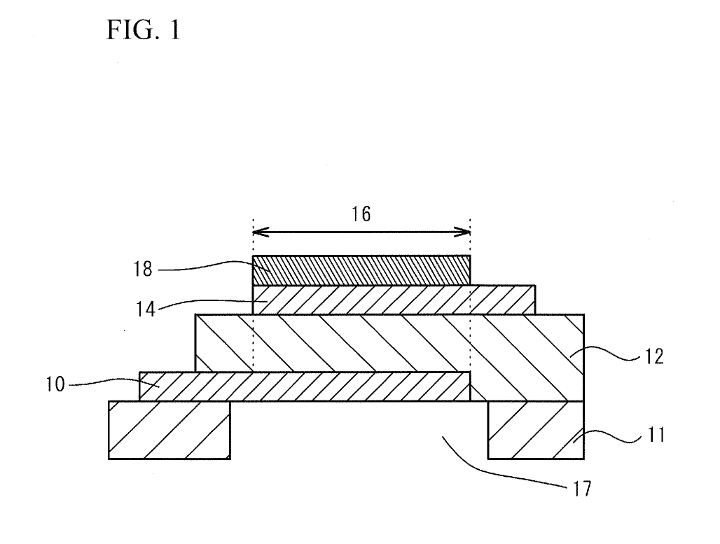

FIG. 1 is a cross-sectional view of a piezoelectric thin-film resonator of a conventional FBAR type, which will be referred to as a first comparative example hereinafter. Referring to FIG. 1, a lower electrode 10 is provided on a substrate. A piezoelectric film 12 formed by a thin film is provided on the lower electrode 10. An upper electrode 14 is provided on the piezoelectric film 12. A resonance portion 16 is defined so that the upper electrode 14 and the lower electrode 10 face each other across the piezoelectric film 12. A weight load film 18 is provided on the upper electrode 14 so as to cover the whole resonance portion 16.

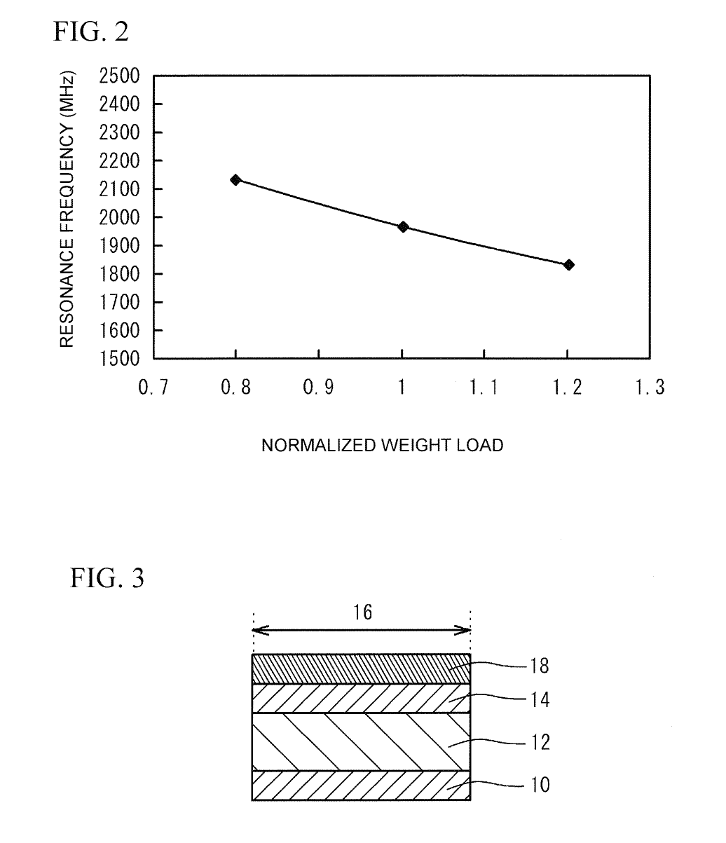

FIG. 2 shows a change of the resonance frequency when the weight of the weight load film 18 of the piezoelectric thin-film resonator of the first comparative example is changed. The horizontal axis of FIG. 2 denotes the normalized weight load, and the vertical axis denotes the resonance frequency. It can be seen from the graph of FIG. 2 that the resonance frequency can be changed by changing the weight of the weight load film 18.

There are two conceivable methods for changing the weight of the weight load film 18 of the piezoelectric thin-film resonator of the first comparative example. More particularly, there are a method for changing the thickness of the weight load film 18 and another method for changing the area thereof. It is to be noted that the method of changing the thickness of the weight load film 18 requires a cumbersome production process for realizing multiple piezoelectric thin-film resonators having mutually different resonance frequencies on the same substrate like the piezoelectric thin-film resonator described in Japanese Patent Application Publication No. 2005-286945. An embodiment capable of solving the above problem will now be described below.

### First Embodiment

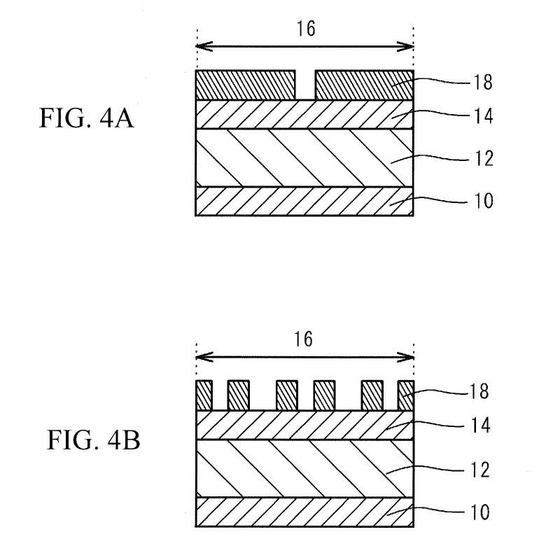

FIG. 3 is a cross-sectional view of a resonance portion of a piezoelectric thin-film resonator in accordance with a second comparative example. FIG. 4A is a cross-sectional view of a resonance portion of a piezoelectric thin-film resonator in accordance with a first embodiment, and FIG. 4B is a cross-sectional view of a resonance portion of a piezoelectric thin-film resonator in accordance with a first variation of the first embodiment. Referring to FIG. 3, the weight load film 18 is provided on the entire surface of the resonance portion 16. The area of the weight load film 18 is the same as that of the resonance portion 16. The lower electrode 10 is made of Ru (ruthenium) and is 250 nm thick. The piezoelectric film 12 is made of AlN (aluminum nitride) and is 1 μm thick. The upper electrode 14 is made of Ru and is 250 nm thick. The weight load film 18 is made of Ti (titanium) and is 100 nm thick. Except the above, the second comparative example is similar to the first comparative example shown in FIG. 1.

Referring to FIG. 4A, the weight load film 18 is provided in the resonance portion 16, and a portion of the weight load film 18 is removed, so that the area of the weight load film 18 is 98% of the area of the resonance portion 16. That is, the area of the weight load film 18 is smaller than that of the resonance portion 16. The other structure of the first embodiment is similar to the second comparative example shown in FIG. 3. Referring to FIG. 4B, multiple portions of the weight load film 18 are removed, so that the weight load film 18 has an area equal to 86% of the area of the resonance portion 16. That is, the area of the weight load film 18 is smaller than that of the resonance portion 16. The other structure of the first variation is similar to that of the second comparative example shown in FIG. 3.

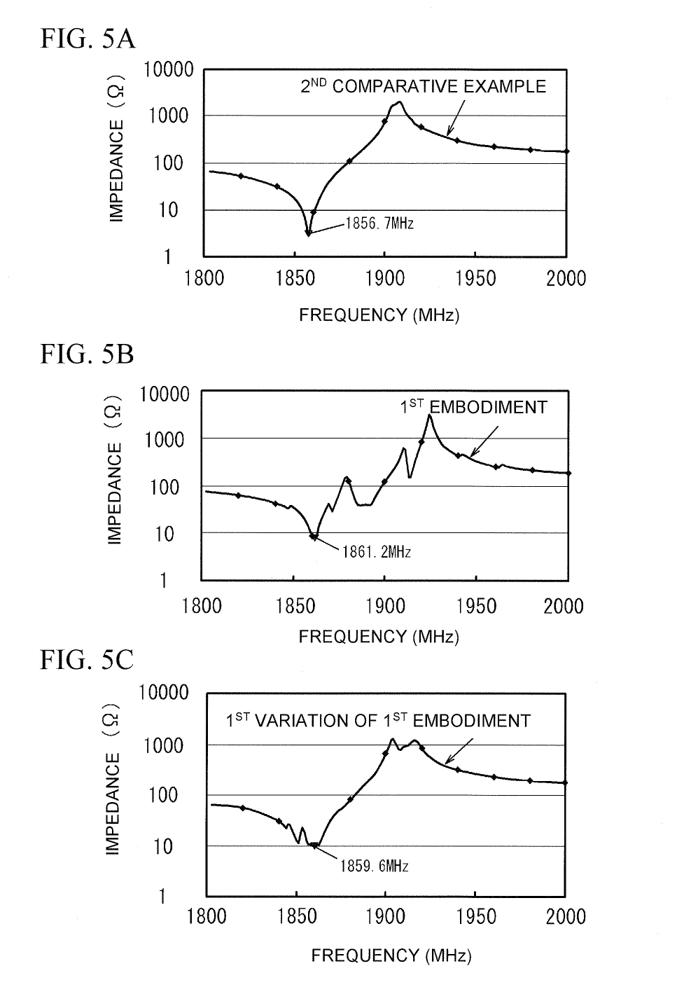

FIGS. 5A through 5C are graphs of the frequency characteristics of the piezoelectric thin-film resonators of the second comparative example, the first embodiment, and the first variation of the first embodiment, respectively. The frequency characteristics of FIGS. 5A through 5C are computed by the finite element method. The horizontal axes of FIGS. 5A through 5C denote the frequency (MHz), and the vertical axes denote the impedance (Ω). Referring to FIG. 5A, the resonance frequency of the second comparative example in which the area of the weight load film 18 is the same as that of the resonance portion is equal to 1856.7 MHz. Referring to FIG. 5B, the resonance frequency of the first embodiment in which a portion of the weight load film 18 is removed is equal to 1861.2 MHz. Referring to FIG. 5C, the resonance frequency of the first variation in which multiple portions of the weight load film 18 are removed is equal to 1859.6 MHz. It can be seen from FIGS. 5A and 5B that the resonance frequency becomes higher by reducing the area of the weight load film 18 to reduce the weight thereof. Similarly, it can be seen from FIGS. 5A and 5C that the resonance frequency becomes higher by reducing the area of the weight load film 18 to reduce the weight thereof. Consequently, it can be seen that reducing the area of the weight load film 18 raises the resonance frequency. It is thus possible to control the resonance frequency by controlling the area of the weight load film 18. Particularly, the resonance frequency can be shifted to a higher frequency side by setting the area of the weight load film 18 smaller than the area of the resonance portion 16.

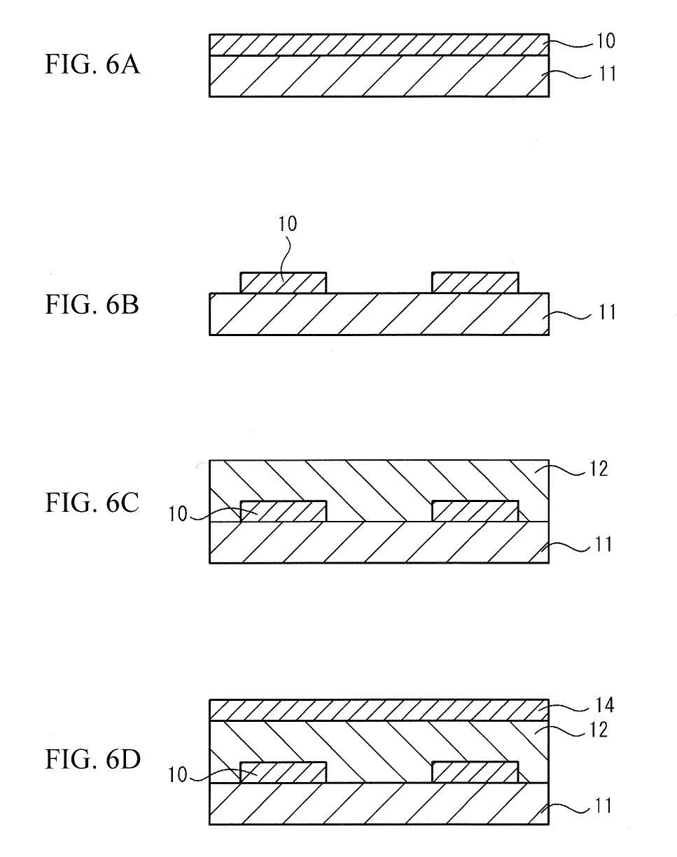

FIGS. 6A through 8B show a method for fabricating the piezoelectric thin-film resonators of the second comparative example and the first embodiment on an identical substrate. Referring to FIG. 6A, a film 10 of Ru having a thickness of 250 nm is grown on the substrate 11 of Si (silicon) by sputtering. Referring to FIG. 6B, the Ru film is shaped into the lower electrodes 10 by the photolithography and etching techniques. Referring to FIG. 6C, the piezoelectric film 12 of AlN having a thickness of 1 μm is grown on the lower electrodes 10 and the substrate 11 by sputtering. Thus, the piezoelectric film 12 is a thin film. Referring to FIG. 6D, a film 14 of Ru having a thickness of 250 nm is grown on the piezoelectric film 12 by sputtering.

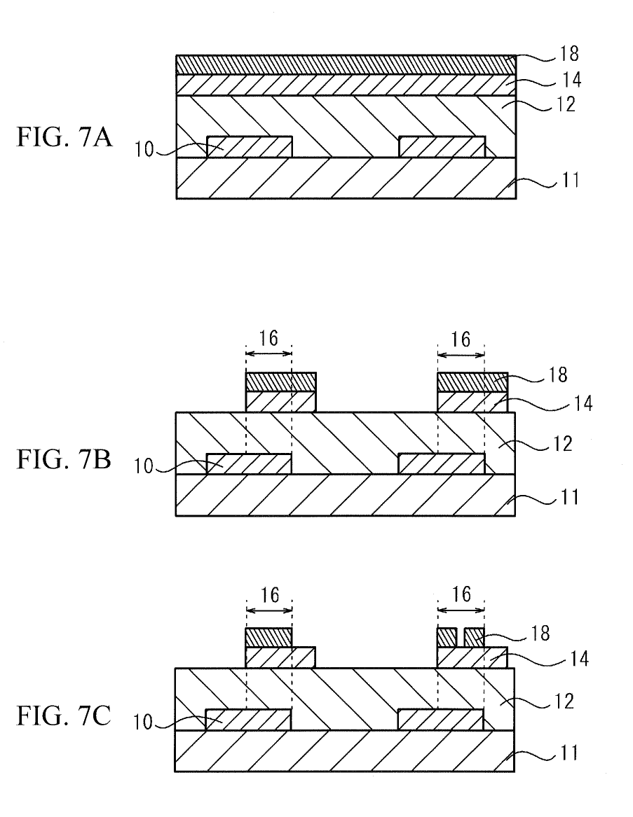

Referring to FIG. 7A, a film 18 of Ti having a thickness of 100 nm is grown on the film 14 by sputtering. Referring to FIG. 7B, the films 14 and 18 are shaped into the upper electrodes 14 and the weight load films 18 by the photolithography and etching techniques. Each resonance portion 16 is defined so that the lower electrode 10 and the upper electrode 14 face each other across the piezoelectric film 12. Multiple resonance portions 16 are formed on the single-piece (identical) substrate 11. Referring to FIG. 7C, the weight load films 18 of the resonance portions 16 are shaped into the respective patterns by the photolithography and etching techniques with masks respectively having the pattern of the second comparative example and the pattern of the first embodiment.

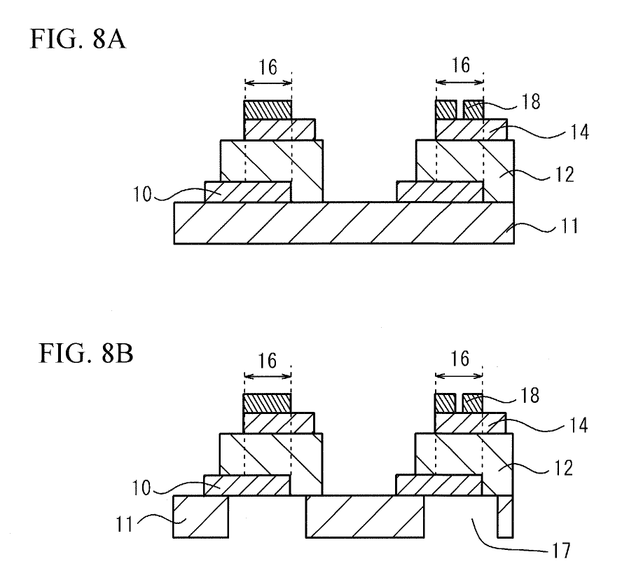

Referring to FIG. 8A, the piezoelectric film 12 is formed into a predetermined shape by the photolithography and etching techniques. Referring to FIG. 8B, the substrate 11 is dry etched from the backside thereof so that via holes 17 located below the resonance portions 16 can be formed in the substrate 11. The piezoelectric thin-film resonators of the second comparative example and the first embodiment can be formed on the same substrate through the above-mentioned process.

According to the first embodiment, it is possible to simultaneously form the weight load films 18 having the patterns of the second comparative example and the first embodiment in the resonance portions 16 by the photolithography and etching techniques with the masks of the respective patterns as shown in FIG. 7C. In other words, it is possible to simultaneously form the weight load films 18 having different areas in the resonance portions 16 by the photolithography and etching techniques with the masks of the respective patterns of the second comparative example and the first embodiment. Therefore, there is no need to repeatedly perform the process of forming the weight load film 18 in order to realize the multiple piezoelectric thin-film resonators of different resonance frequencies, as described in Japanese Patent Application Publication No. 2005-286945. A reduced number of process steps is capable of realizing multiple piezoelectric thin-film resonators of different resonance frequencies on the same substrate or chip. This reduces the production cost.

In the above description, the weight load film 18 of the first embodiment is made of Ti. Another material may be used as long as a portion of the film made of this material can be removed by etching or the like. The substrate 11, the lower electrode 10, the piezoelectric film 12 and the upper electrode 14 are not limited to the materials but may be made of other materials described in the related art section of the present specification.

### Second Embodiment

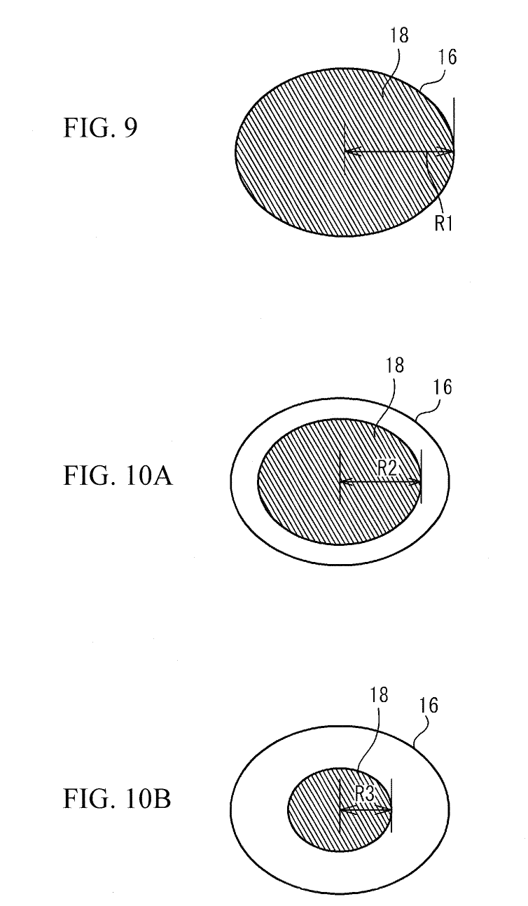

FIG. 9 is a plan view of a resonance portion of a piezoelectric thin-film resonator in accordance with a third comparative example. FIG. 10A is a plan view of a resonance portion of a piezoelectric thin-film resonator in accordance with a second embodiment, and FIG. 10B is a plan view of a resonance portion of a piezoelectric thin-film resonator in accordance with a first variation of the second embodiment.

Referring to FIG. 9, the weight load film 18 is provided on the entire surface of the resonance portion 16. The resonance portion 16, namely, the weight load film 18 has a radium R1 of 100 μm along the major axis. The lower electrode 10 is made of Ru and is 250 nm thick, the piezoelectric film 12 is made of AlN and is 1 μm thick, and the upper electrode 14 is made of Ru and is 250 nm thick, and the weight load film 18 is made of Ti and is 100 nm thick. The other structure is the same as that of the first comparative example.

Referring to FIG. 10A, the weight load film 18 is provided in the resonance portion 16, and has a shape approximately similar to that of the resonance portion 16. The area of the weight load film 18 is smaller than that of the resonance portion 16, that is, smaller than the area of the weight load film 18 of the third comparative example. The weight load film 18 has a radius R2 of 75 μm along the major axis, which is ¾ of the radius R1 of the resonance portion 16. Thus, the area of the weight load film 18 is approximately 56% of the area of the resonance portion 16. The other structure is the same as that of the third comparative example.

Referring to FIG. 10B, the weight load film 18 has a shape approximately similar to that of the resonance portion 16, and has an area smaller than that of the weight load film 18 of the third comparative example. The weight load film 18 has a radius R3 of 50 μm along the major axis, which is ½ of the radius R1 of the resonance portion 16 along the major axis. Thus, the area of the weight load film 18 is approximately 25% of the area of the resonance portion 16. The other structure is the same as that of the third comparative example.

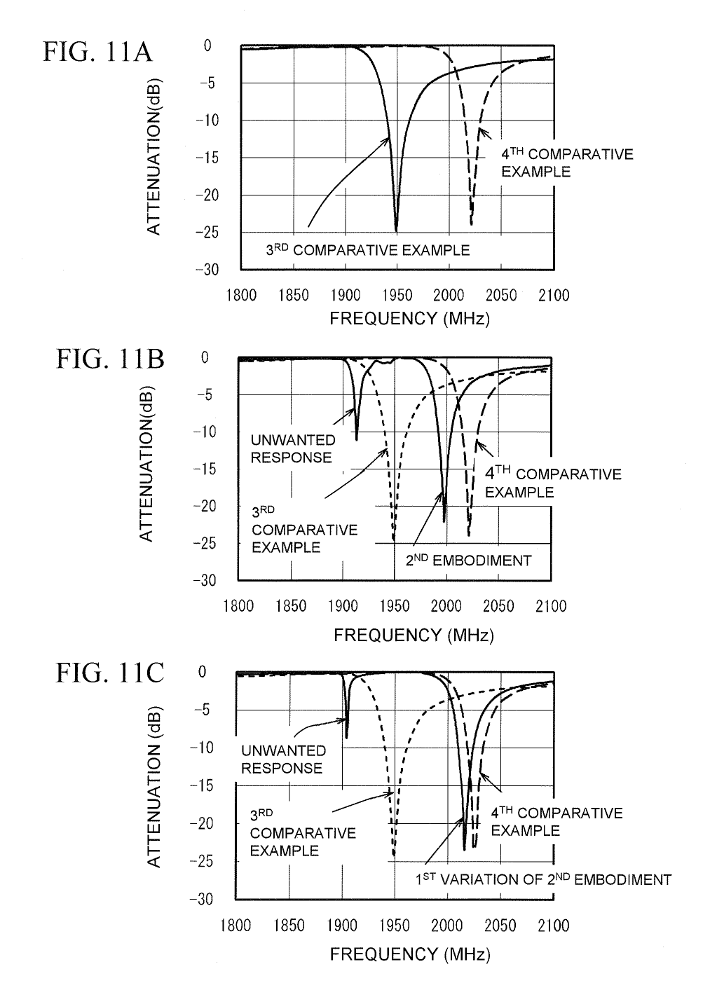

FIG. 11A shows a bandpass characteristic of the piezoelectric thin-film resonator of the third comparative example, FIG. 11B shows a bandpass characteristic of the piezoelectric thin-film resonator of the second embodiment, and FIG. 11C shows a bandpass characteristic of the piezoelectric thin-film resonator of the first variation of the second embodiment. Fourth comparative examples shown in FIGS. 11A through 11C do not have the weight load films 18 in the respective piezoelectric thin-film resonators.

Referring to FIGS. 11A and 11B, the resonance frequency of the second embodiment in which the areas of the weight load film 18 is smaller than that of the third comparative example is higher than the resonance frequency of the third comparative example in which the area of the weight load film 18 is equal to that of the resonance portion 16. A solid line in FIG. 11B shows the bandpass characteristic of the second embodiment. Similarly, referring to FIGS. 11A and 11C, the resonance frequency of the first variation of the second embodiment in which the area of the weight load film 18 is smaller than that of the weight load film 18 of the third comparative example is higher than the resonance frequency of the third comparative example. A solid line in FIG. 11C shows the bandpass characteristic of the first variation of the second embodiment. Unwanted responses that appear on the low-frequency sides of the pass bands shown in FIGS. 11B and 11C have small amounts of attenuation due to resonance of acoustic waves other than the thickness-extensional vibrations of the piezoelectric thin-film resonators. The unwanted responses degrade the suppression characteristic and the good frequency response, and are preferably as small as possible.

When the shape of the weight load film 18 is similar to that of the resonance portion 16, the resonance frequency of the piezoelectric thin-film resonator can be controlled by controlling the area of the weight load film 18. Particularly, when the area of the weight load film 18 is equal to that of the resonance portion 16, the lowest resonance frequency is available. As the area of the weight load film 18 becomes smaller than that of the resonance portion 16, the resonance frequency becomes higher.

The resonance portion 16 is not limited to an oval shape but may have a circular, square, rectangular or polygonal shape.

### Third Embodiment

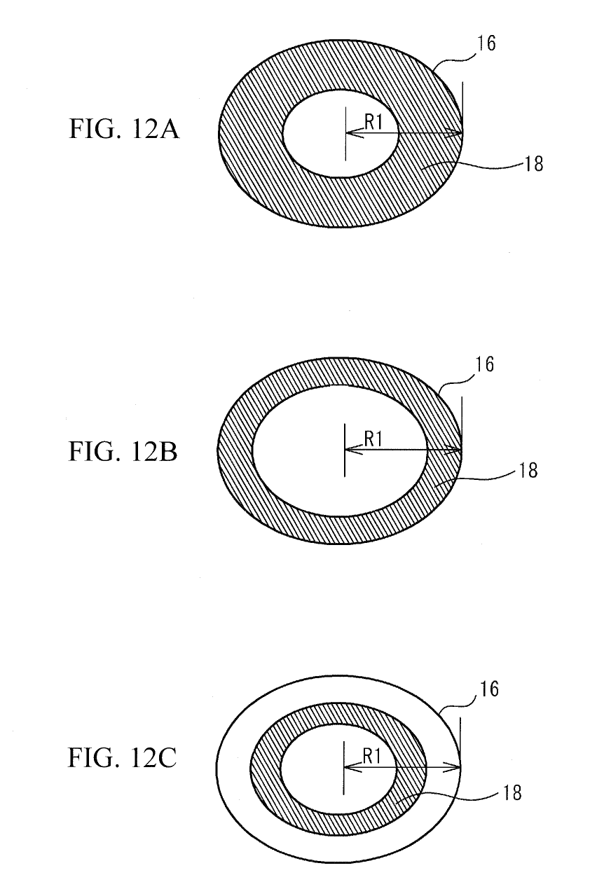

FIG. 12A is a plan view of a resonance portion of a piezoelectric thin-film resonator in accordance with a third embodiment, FIG. 12B is a plan view of a resonance portion of a piezoelectric thin-film resonator in accordance with a first variation of the third embodiment, and FIG. 12C is a plan view of a resonance portion of a piezoelectric thin-film resonator in accordance with a second variation of the third embodiment.

Referring to FIG. 12A, the weight load film 18 is provided in the resonance portion 16 and is formed into a ring shape. In other words, the weight load film 18 has a hollow in the center. The weight load film 18 has an area smaller than that of the resonance portion 16, that is, smaller than the areas of the weight load film of the third comparative example. The weight load film 18 is provided in the range of ½ of the radius R1 of the resonance portion 16 from the outer end of the resonance portion 16. Thus, the area of the weight load film 18 is approximately 75% of the area of the resonance portion 16. The other structure is the same as that of the third comparative example.

Referring to FIG. 12B, the weight load film 18 is formed into a ring shape, and has an area smaller than that of the weight load film 18 of the third comparative example. The weight load film 18 is provided within the range of ¼ of the radius R1 of the resonance portion 16 from the outer end of the resonance portion 16. Thus, the area of the weight load film 18 is approximately 44% of the area of the resonance portion 16. The other structure is the same as that of the third comparative example.

Referring to FIG. 12C, the weight load film 18 has a ring shape and an area smaller than that of the weight load film 18 of the third comparative example. The weight load film 18 is provided within a region ranging from ½ of the radius R1 of the resonance portion 16 from the outer end of the resonance portion to ¼ of the radius R1 of the resonance portion 16. In other words, the weight load film 18 is provided in the region ranging from the region of the weight load film 18 of the second embodiment to the region of the weight load film 18 of the first variation of the second embodiment. Thus, the area of the weight load film 18 is approximately 31% of the area of the resonance portion 16. The other structure is the same as that of the third comparative example.

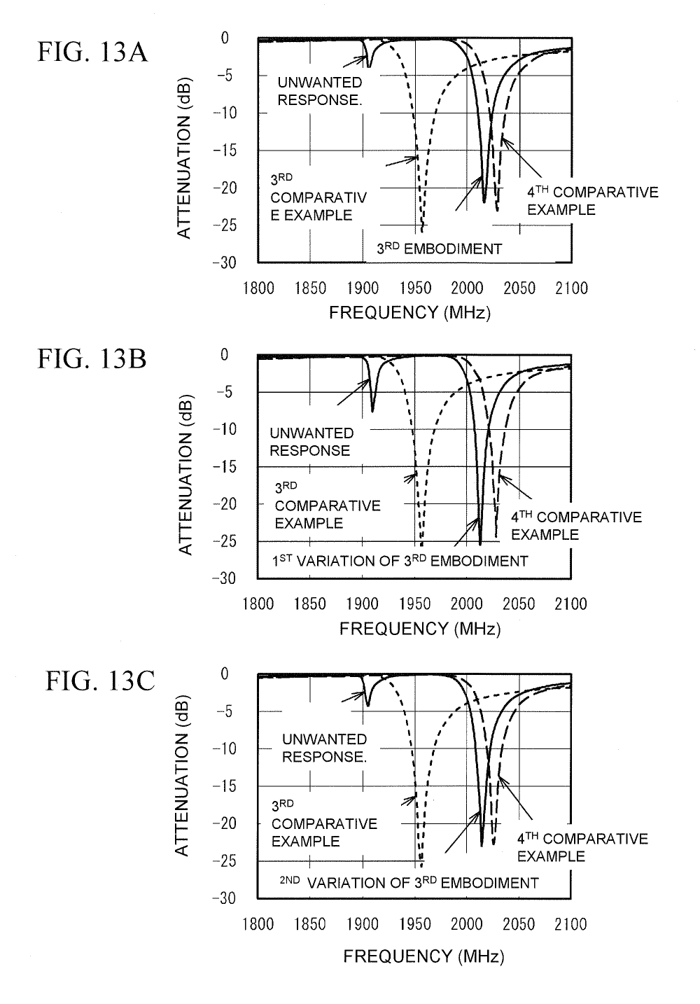

FIG. 13A shows a bandpass characteristic of the piezoelectric thin-film resonator of the third embodiment, FIG. 13B shows a bandpass characteristic of the piezoelectric thin-film resonator of the first variation of the third embodiment, and FIG. 13C shows a bandpass characteristic of the piezoelectric thin-film resonator of the second variation of the third embodiment. The resonance frequencies of the third embodiment, the first variation of the third embodiment, and the second variation thereof each having the respective area of the weight load film 18 smaller than that of the third comparative example are higher than the resonance frequency of the third comparative example. Solid lines shown in FIGS. 13A, 13B and 13C are the bandpass characteristics of the third embodiment, the first variation of the third embodiment, and the second variation thereof, respectively.

As described above, even when the weight load film 18 has a ring shape, the resonance frequency of the piezoelectric thin-film resonator can be shifted to the higher side by setting the area of the weight load film 18 smaller than the area of the resonance portion 16.

According to the third embodiment, the unwanted responses that appear on the low-frequency sides of the pass bands shown in FIGS. 13A through 13C can be much more reduced than those in the second embodiment shown in FIGS. 11B and 11C.

### Fourth Embodiment

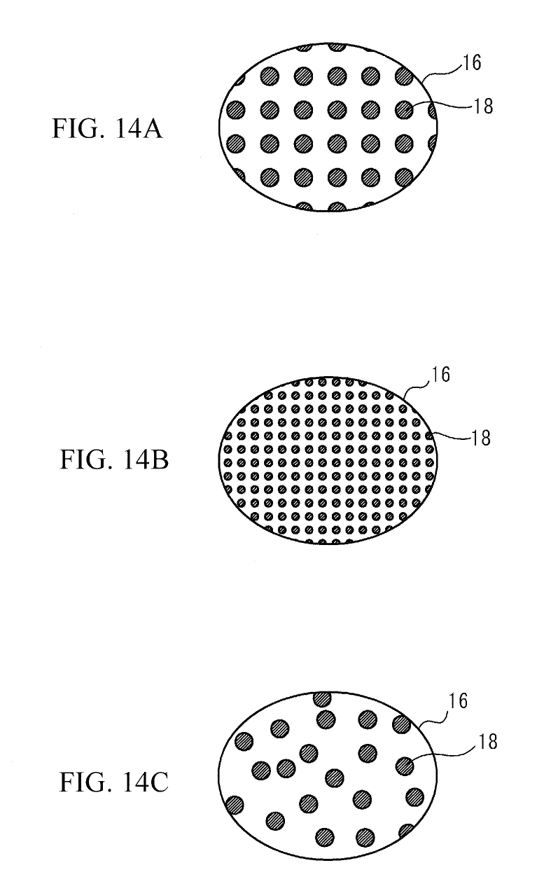

FIG. 14A is a plan view of a resonance portion of a piezoelectric thin-film resonator in accordance with a fourth embodiment, FIG. 14B is a plan view of a resonance portion of a piezoelectric thin-film resonator in accordance with a first variation of the fourth embodiment, and FIG. 14C is a plan view of a resonance portion of a piezoelectric thin-film resonator in accordance with a second variation of the fourth embodiment.

Referring to FIG. 14A, the weight load film 18 is provided in the resonance portion 16, and is composed of circular cylinders, which are periodically arranged and have a diameter of 22 μm. The weight load film 18 is composed of multiple patterned portions. The area of the weight load film 18 is approximately 35% of the area of the resonance portion 16. The other structure is the same as that of the third comparative example.

Referring to FIG. 14B, the weight load film 18 is provided in the resonance portion 16, and is composed of circular cylinders, which are periodically arranged and have a diameter of 7.5 μm. The area of the weight load film 18 is approximately 32% of the area of the resonance portion 16. The other structure is the same as that of the third comparative example.

Referring to FIG. 14C, the weight load film 18 is provided in the resonance portion 16, and is composed of circular cylinders, which are arranged at random and have a diameter of 22 μm. The area of the weight load film 18 is approximately 33% of the area of the resonance portion 16. The other structure is the same as that of the third comparative example.

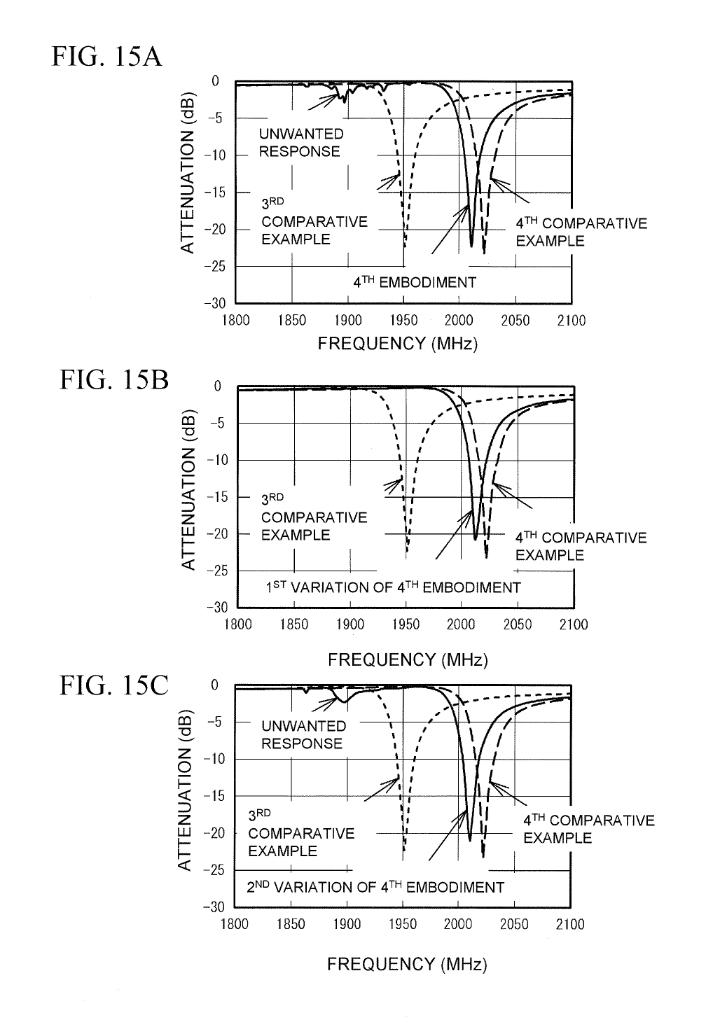

FIG. 15A shows a bandpass characteristic of the piezoelectric thin-film resonator of the fourth embodiment, FIG. 13B shows a bandpass characteristic of the piezoelectric thin-film resonator of the first variation of the fourth embodiment, and FIG. 13C shows a bandpass characteristic of the piezoelectric thin-film resonator of the second variation of the fourth embodiment. The resonance frequencies of the fourth embodiment, the first variation of the fourth embodiment, and the second variation thereof each having the respective area of the weight load film 18 smaller than that of the third comparative example are higher than the resonance frequency of the third comparative example. Solid lines shown in FIGS. 15A, 15B and 15C are the bandpass characteristics of the fourth embodiment, the first variation of the fourth embodiment, and the second variation thereof, respectively.

As described above, even when the weight load film 18 is composed of multiple patterned portions, the resonance frequency of the piezoelectric thin-film resonator can be shifted to the higher side by setting the area of the weight load film 18 smaller than the area of the resonance portion 16.

According to the fourth embodiment, the unwanted responses that appear on the low-frequency sides of the pass bands shown in FIGS. 15A through 15C can be much more reduced than those in the third embodiment shown in FIGS. 13A through 13C.

The weight load film 18 of the fourth embodiment is not limited to the circular cylinders but may have an oval or rectangular shape or an arbitrary shape or may have multiple patterns in which different shapes of the weight load film 18 are mixed.

### Fifth Embodiment

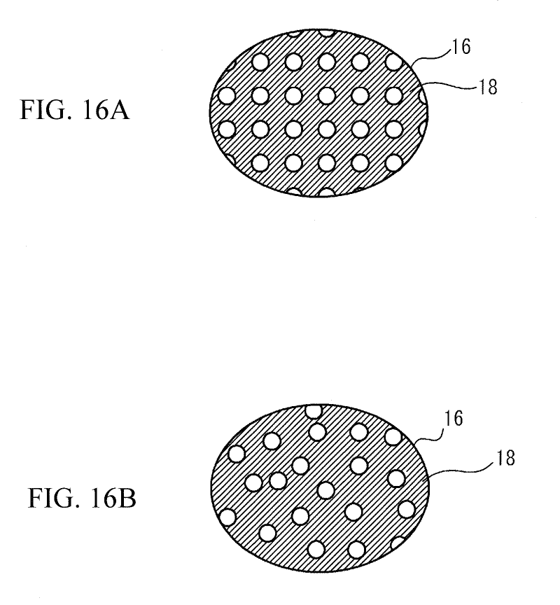

FIG. 16A is a plan view of a resonance portion of a piezoelectric thin-film resonator in accordance with a fifth embodiment, and FIG. 16B is a plan view of a resonance portion of the piezoelectric thin-film resonator in accordance with a first variation of the fifth embodiment.

Referring to FIG. 16A, the weight load film 18 is provided in the resonance section 16, and has circular holes that are periodically arranged. The weight load film 18 has a pattern of holes arranged at given intervals. The other structure is the same as that of the third comparative example.

Referring to FIG. 16B, the weight load film 18 is provided in the resonance section, and has circular holes that are arranged at random. The other structure is the same as that of the third comparative example.

According to the fifth embodiment, the holes formed in the weight load film 18 result in an area smaller than that of the resonance portion 16, so that the resonance frequency of the piezoelectric thin-film resonator can be made higher.

The holes formed in the weight load film 18 are not limited to the circular shape but may have an oval or rectangular shape or another arbitrary shape. Different shapes of holes may be mixed.

### Sixth Embodiment

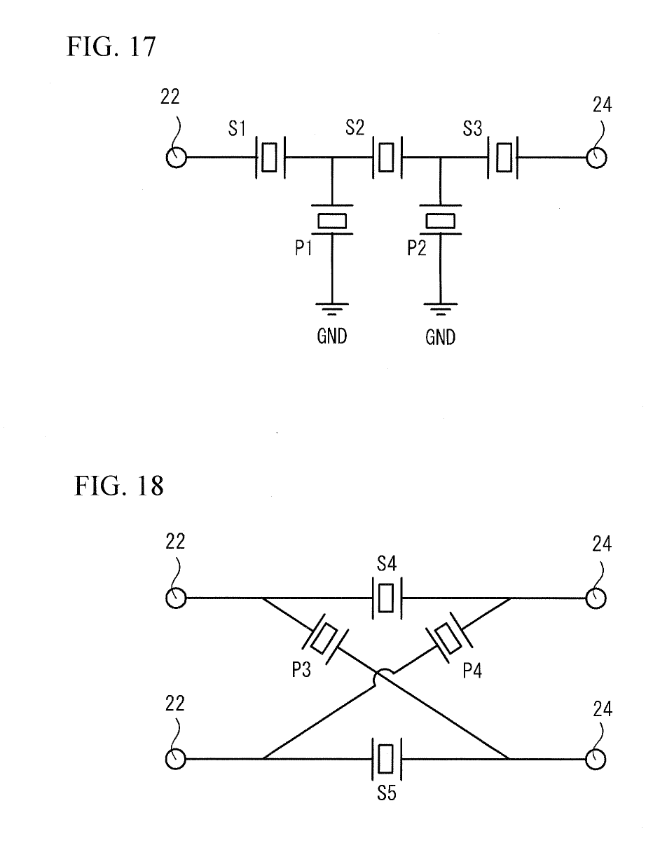

A sixth embodiment is an application of the piezoelectric thin-film resonator of the first embodiment to one-port resonators that form a ladder type filter. FIG. 17 shows a configuration of the above ladder type filter. Referring to FIG. 17, the ladder type filter is composed of one-port series resonators S1 through S3 connected in series between an input terminal 22 and an output terminal 24, and one-port parallel resonators P1 and P2. The parallel resonator P1 is connected between a node at which the series resonators S1 and S2 are connected and ground. The parallel resonator P2 is connected between a node at which the series resonators S2 and S3 are connected and ground. The series resonators S1 through S3 and the parallel resonators P1 and P2 are respectively formed by the piezoelectric thin-film resonators of the first embodiment.

Generally, a bandpass characteristic of the ladder type filter is defined by setting the resonance frequencies of the series resonators S1 through S3 higher than those of the parallel resonators P1 and P2. The resonance frequencies of the piezoelectric thin-film resonators of the first embodiment can be controlled by controlling the weight load films 18. Thus, the areas of the weight load films 18 of the series resonators are set smaller than those of the weight load films 18 of the parallel resonators, so that the resonance frequencies of the series resonators can be made higher than those of the parallel resonators. That is, the piezoelectric thin-film resonators may have the respective weight load films 18 having respectively areas in order to separately control the resonance frequencies of the series and parallel resonators. It is thus possible to realize ladder filters having desired frequency characteristics. The weight load films 18 may be omitted from the series resonators. The control of the areas of the piezoelectric thin-film resonators improves the flexibility of design of filters.

As described above, a desired bandpass filter characteristic can be realized by forming the ladder type filer with at least two piezoelectric thin-film resonators having different areas of the weight load films 18. Preferably, the ladder type filter has at least one piezoelectric thin-film resonator in which the areas of the weight load film 18 is equal to that of the resonance portion 16.

The present invention is not limited to the ladder type filter of the sixth embodiment but may include another type of acoustic wave device such as a lattice type filter. FIG. 18 shows an exemplary structure of the lattice type filter. A one-port piezoelectric thin-film resonator S4 is provided between an input terminal 22 and an output terminal 24, and a one-port piezoelectric thin-film resonator S5 is provided between another input terminal 22 and another output terminal 24. A one-port piezoelectric thin-film resonator P3 is connected between the input terminal 22 to which the resonator S4 is connected and the output terminal 24 to which the resonator S5 is connected. A one-port piezoelectric thin-film resonator P4 is connected between the input terminal 22 to which the resonator S5 is connected and the output terminal 24 to which the resonator P4 is connected. The resonators S4 and S5 are series resonators, and the resonators P3 and P4 are parallel resonators.

The piezoelectric thin-film resonators of any of the second through fifth embodiments may be applied to the ladder type or lattice type filters or another type of filter.

The piezoelectric thin-film resonators of the first through fifth embodiments are not limited to the FBAR type but may be of SMR type. In this alternative, similar advantages are obtained.

The present invention is not limited to the specifically disclosed embodiments, but may include other embodiments and variations without departing from the scope of the present invention.

The present application is based on Japanese Patent Application No. 2007-003357 filed on Jan. 11, 2007, the entire disclosure of which is hereby incorporated by reference.

What is claimed is:

1. A piezoelectric thin-film resonator comprising:
a lower electrode provided on a substrate;
a piezoelectric film provided on the lower electrode;
an upper electrode provided on the piezoelectric film so as to face the lower electrode across the piezoelectric film to thus define a resonance portion; and
a weight load film provided on the upper electrode,
the weight load film being provided in the resonance portion and having an area smaller than that of the resonance portion.

2. The piezoelectric thin-film resonator as claimed in claim 1, wherein the weight load film has a shape similar to that of the resonance portion.

3. The piezoelectric thin-film resonator as claimed in claim 1, wherein the weight load film has a ring shape.

4. The piezoelectric thin-film resonator as claimed in claim 1, wherein the weight load film has multiple patterned portions.

5. The piezoelectric thin-film resonator as claimed in claim 1, wherein the weight load film has holes.

6. An acoustic wave device comprising a piezoelectric thin-film resonator including:
a lower electrode provided on a substrate;
a piezoelectric film provided on the lower electrode;
an upper electrode provided on the piezoelectric film so as to face the lower electrode across the piezoelectric film to thus define a resonance portion; and
a weight load film provided on the upper electrode,
the weight load film being provided in the resonance portion and having an area smaller than that of the resonance portion.

7. An acoustic wave device comprising piezoelectric thin-film resonators each including:
a lower electrode provided on a substrate;
a piezoelectric film provided on the lower electrode;
an upper electrode provided on the piezoelectric film so as to face the lower electrode across the piezoelectric film to thus define a resonance portion; and
a weight load film provided on the upper electrode,
the weight load film being provided in the resonance portion and having an area smaller than that of the resonance portion,
the weight load films of the piezoelectric thin-film resonators having different areas.

8. An acoustic wave device comprising piezoelectric thin-film resonators each including:
a lower electrode provided on a substrate;
a piezoelectric film provided on the lower electrode;
an upper electrode provided on the piezoelectric film so as to face the lower electrode across the piezoelectric film to thus define a resonance portion; and
a weight load film provided on the upper electrode,
the weight load film being provided in the resonance portion and having an area smaller than that of the resonance portion,
the piezoelectric thin-film resonators including resonators having the weight load films having an identical area.

9. The acoustic wave device as claimed in claim 7, wherein the acoustic wave device is a ladder type filter.

10. The acoustic wave device as claimed in claim 8, wherein the acoustic wave device is a ladder type filter.

11. A method comprising:
forming multiple resonance portions in each of which a lower electrode and an upper electrode face each other across a piezoelectric film; and
simultaneously forming weight load films having different areas in the multiple resonance portions.

12. The method as claimed in claim 11, wherein simultaneously forming the weight load films use masks having different patterns corresponding to shapes of the weight load films in the multiple resonance portions.
